(19) United States
(12) Patent Application Publication
(10) Pub. No.: US 2013/0160948 A1
(43) Pub. Date: Jun. 27, 2013

(54) Plasma Processing Devices With Corrosion Resistant Components

(71) Applicants: Hong Shih, Santa Clara, CA (US); Lin Xu, Katy, TX (US); Rajinder Dhindsa, Pleasanton, CA (US); John Daugherty, Fremont, CA (US); Yan Fang, Fremont, CA (US); Siwen Li, San Jose, CA (US)

(72) Inventors: Hong Shih, Santa Clara, CA (US); Lin Xu, Katy, TX (US); Rajinder Dhindsa, Pleasanton, CA (US); John Daugherty, Fremont, CA (US); Yan Fang, Fremont, CA (US); Siwen Li, San Jose, CA (US)

(73) Assignee: LAM RESEARCH CORPORATION, Fremont, CA (US)

(21) Appl. No.: 13/370,765

(22) Filed: Feb. 10, 2012

Related U.S. Application Data
(60) Provisional application No. 61/579,716, filed on Dec. 23, 2011.

(51) Int. Cl. B05C 5/02; C23C 16/50

(52) U.S. Cl. 156/345.33; 118/723 R

(57) ABSTRACT

In one embodiment, a plasma processing device may include a plasma processing chamber, a plasma region, an energy source, and a corrosion resistant component. The plasma processing chamber can be maintained at a vacuum pressure and can confine a plasma processing gas. The energy source can transmit energy into the plasma processing chamber and transform at least a portion of the plasma processing gas into plasma within the plasma region. The corrosion resistant component can be located within the plasma processing chamber. The corrosion resistant component can be exposed to the plasma processing gas and is not coincident with the plasma region. The corrosion resistant component may include an inner layer of stainless steel that is coated with an outer layer of Tantalum (Ta).

### CROSS-REFERENCE TO RELATED APPLICATIONS

This application claims the benefit of U.S. Provisional Application No. 61/579,716 filed Dec. 23, 2011, entitled “PLASMA PROCESSING DEVICES WITH CORROSION RESISTANT COMPONENTS.” The entire content of said application is hereby incorporated by reference.

### TECHNICAL FIELD

The present specification generally relates to plasma processing devices with corrosion resistant components, more specifically, to plasma processing devices with corrosion resistant components comprising Tantalum (Ta).

### BACKGROUND

Plasma processing devices can be utilized to etch material away from and/or deposit material onto a substrate formed from, for example, a semiconductor or glass. Plasma processing devices may contain a vacuum chamber that encloses plasma processing gas, which can be ionized and transformed into plasma. For example an energized source (radio frequency (RF), microwave or other source) can apply energy to the plasma processing gas to ignite plasma. The components of the plasma processing devices may be maintained at various direct current (DC) or RF voltage levels throughout plasma processing. Accordingly, various conductive components can be utilized (e.g., metallic materials).

Plasma processing gases commonly include caustic gases (e.g., halogens) and non-caustic gases that can cause corrosion to metallic materials. When corrosion is significant the components formed from metallic materials may need to be removed to prevent failure of the plasma process and/or the introduction of defects on the substrate.

Accordingly, a need exists for alternative plasma processing devices with corrosion resistant components comprising Tantalum (Ta).

### SUMMARY

In one embodiment, a plasma processing device may include a plasma processing chamber, a gas distribution member, a substrate support member, a plasma region, an energy source, and a corrosion resistant component. The plasma processing chamber can be maintained at a vacuum pressure and can confine a plasma processing gas. The gas distribution member and the substrate support member can be disposed within the plasma processing chamber. The gas distribution member can emit the plasma processing gas within the plasma processing chamber. The gas distribution member and the substrate support member can be separated from one another by the plasma region. The energy source can be in electrical communication with the gas distribution member, the substrate support member, or both. The energy source can transmit energy into the plasma processing chamber and transform at least a portion of the plasma processing gas into plasma within the plasma region. The corrosion resistant component can be located within the plasma processing chamber. The corrosion resistant component can be exposed to the plasma processing gas and is not coincident with the plasma region. The corrosion resistant component may include an inner layer of stainless steel that is coated with an outer layer of Tantalum (Ta).

In another embodiment, a plasma processing device may include a plasma processing chamber, a gas distribution member, a substrate support member, a plasma region, an energy source, and a corrosion resistant component. The plasma processing chamber can be maintained at a vacuum pressure and can confine a plasma processing gas. The gas distribution member and the substrate support member can be disposed within the plasma processing chamber. The gas distribution member can emit the plasma processing gas within the plasma processing chamber. The gas distribution member and the substrate support member can be separated from one another by the plasma region. The energy source can be in electrical communication with the gas distribution member, the substrate support member, or both. The energy source can transmit energy into the plasma processing chamber and transform at least a portion of the plasma processing gas into plasma within the plasma region. The corrosion resistant component can be located within the plasma processing chamber. The corrosion resistant component can be exposed to the plasma processing gas and is not coincident with the plasma region. The corrosion resistant component may include an inner layer of stainless steel that is coated with an outer layer of Tantalum (Ta). The outer layer of Tantalum (Ta) can have a thickness of less than about 100 μm. The outer layer of Tantalum (Ta) can have a porosity of less than about 5%. The outer layer of Tantalum (Ta) may include at least about 97 wt % of Tantalum (Ta).

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a plasma processing device according to one or more embodiments shown and described herein; and

FIG. 2 schematically depicts a cut away view of a corrosion resistant layered structure according to one or more embodiments shown and described herein.

### DETAILED DESCRIPTION

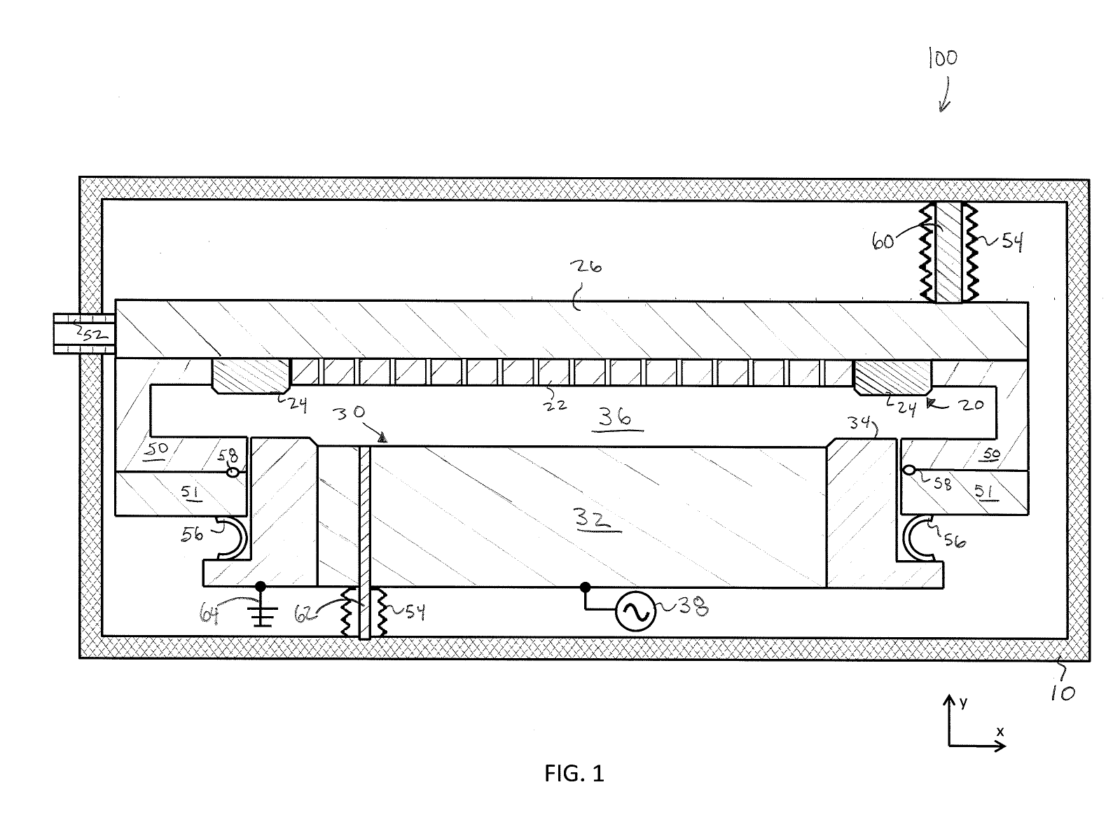

As is noted above, the present disclosure relates to plasma processing devices for etching and/or depositing material on a substrate. Referring to FIG. 1, the plasma processing device generally comprises a plasma processing chamber, a gas distribution member, a substrate support member, a plasma region defined between the gas distribution member and substrate support member, an energy source for generating plasma, and a corrosion resistant component. Various embodiments of the plasma processing device and the operation of the plasma processing device will be described in more detail herein.

Referring now to FIG. 1, the plasma processing device 100 comprises a plasma processing chamber 10 for confining plasma processing gas during processing of a desired substrate. The plasma processing chamber 10 can be formed from a metallic material that can be set to a reference potential. A substrate (not depicted in FIG. 1) can be located within the plasma processing chamber 10 for plasma processing. For example, the substrate can be clamped in place with a substrate support member 30. The plasma processing chamber 10 can be maintained at a wide range of vacuum pressures such as, for example, about 1-1000 mTorr, or about 100 mTorr to about 200 mTorr in some embodiments.

A gas distribution member 20 is disposed within the plasma processing chamber 10 for emitting plasma processing gas into the plasma processing chamber 10. The plasma processing gas may comprise halogens or halogen elements such as, for example, fluorine (F), chlorine (Cl), bromine (Br), iodine (I), and astatine (At). Moreover, specific process gases may include CClF₃, C₄F₈, C₄F₆, CHF₃, CH₂F₃, CF₄, CH₃F, C₂F₄, N₂, CO, O₂, Ar, Xe, He, H₂, NH₃, SF₆ , BCl₃, HBr, HCl, Cl₂, and other equivalent plasma processing gases. In one embodiment, the gas distribution member 20 can comprise an inner showerhead electrode 22 with a plurality of gas passages for emitting plasma processing gas and an outer electrode 24. The inner showerhead electrode 22 and the outer electrode 24 can be formed from silicon carbide, single crystal silicon or other suitable material for semiconductor processing.

The plasma processing device 100 further comprises a substrate support member 30 disposed within the plasma processing chamber 10 for aligning a substrate during plasma processing. In one embodiment, the substrate support member 30 can comprise an electrostatic chuck 32 that is at least partially surrounded by an outer alignment member 34. The electrostatic chuck 32 can include a conductive portion that is covered by a dielectric layer. The conductive portion can be charged to a relatively high voltage with respect to the substrate to generate an electrostatic force to clamp the substrate to the electrostatic chuck 32. The outer alignment member 34 can be raised (e.g., extend further along the y-axis) with respect to the electrostatic chuck 32. Furthermore, the outer alignment member 34 can be beveled to receive and align the substrate with respect to the electrostatic chuck 32. In some embodiments, the outer alignment member 34 can be formed from a dielectric material. The dielectric material can be, for example, quartz, fused silica, silicon nitride, alumina, plastic material, and any other suitable refractory material.

The energy source 38 is configured to supply energy sufficient to transform at least a portion of the plasma processing gas into plasma within the plasma region 36. For example, the energy source 38 can be in electrical communication with the gas distribution member, the substrate support member, or both. The energy source 38 can be any device capable of supplying sufficient ionizing energy into the plasma region of the plasma processing chamber 10 such as, for example, a radio frequency (RF) generator. As is described in greater detail below, the energy source 38 can be configured to generate electromagnetic energy for a capacitive coupled plasma arrangement. It is noted that while the energy source 38 is depicted in FIG. 1 as a single source in electrical communication with the electrostatic chuck 32, the energy source 38 may include any number of discrete sources for generating ionizing energy.

In further embodiments, the energy source 38 may be configured to generate electromagnetic energy for an inductively coupled plasma reactor. Thus, while not depicted in FIG. 1, the energy source 38 can include one or more coils such as, for example, faceted concentric segments concentric segments that are formed at angular turns with respect to one another, solenoid shaped conductors, toroid shaped conductors or combinations thereof. Furthermore, it is noted that “electrical communication,” as used herein, means that components are capable of exchanging signals with one another such as, for example, electrical signals via conductive medium, electromagnetic signals via air, and the like. The term “signal” means a waveform (e.g., electrical, magnetic, or electromagnetic), such as DC, AC, sinusoidal-wave, triangular-wave, square-wave, and the like, capable of traveling through a medium.

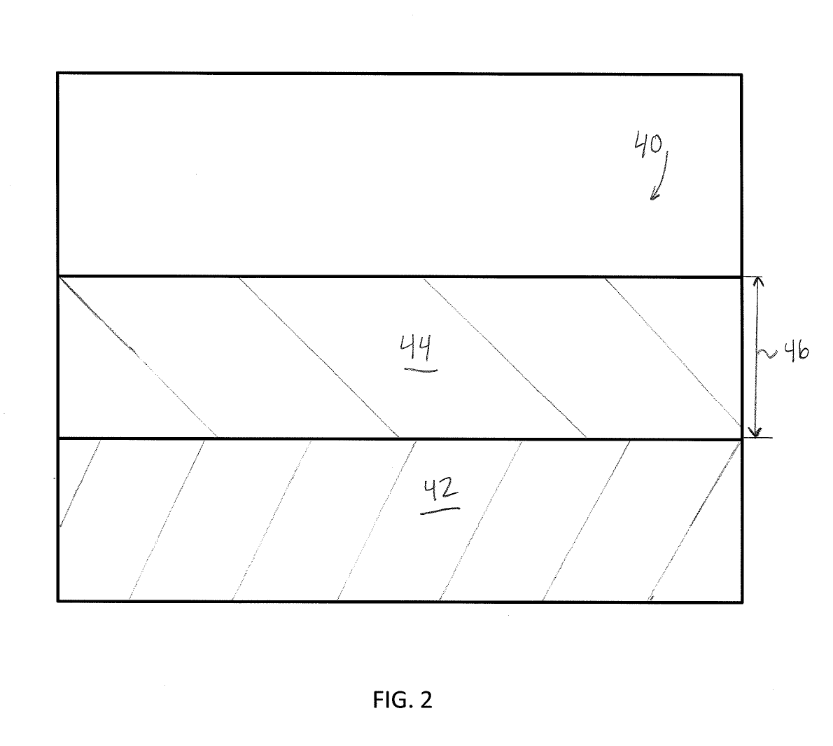

The plasma processing device 100 may include one or more corrosion resistant components located within the plasma processing chamber 10. Specifically, with reference to FIG. 2, each of the corrosion resistant components comprises a corrosion resistant layered structure 40. The corrosion resistant layered structure 40 comprises an inner layer 42 of stainless steel. The inner layer 42 of stainless steel can be a coating that is alloyed onto a base material or the base material. The inner layer 42 of stainless steel of the corrosion resistant layered structure 40 is coated with an outer layer 44 of Tantalum (Ta). The outer layer 44 of Tantalum (Ta) can have a relatively low resistivity (about 1.2×¹⁰⁻⁷ ohm-cm) with respect to the inner layer 42 of stainless steel conductive (e.g., about 1.2×¹⁰⁻⁷ ohm-cm for 316L stainless steel). Accordingly, the outer layer 44 of Tantalum (Ta) can be coupled to other conductors to maintain RF/DC current continuity. It has been discovered that the outer layer 44 of Tantalum (Ta) can be substantially resistant to radical attacks without ion bombardment in plasma applications. Accordingly, the outer layer 44 of Tantalum (Ta) can be exposed to the plasma processing gas without substantial amounts of corrosion.

The inner layer 42 of stainless steel is formed from any alloy type, grade or surface finish of stainless steel suitable to endure exposure to the plasma processing gas described herein such as, for example, stainless steel types covered under ASTM A-967. Suitable stainless steel alloys may comprise molybdenum, titanium, austenitic chromium-nickel-manganese alloys, austenitic chromium-nickel-manganese alloys, austenitic chromium-nickel alloys, ferritic chromium alloys, martensitic chromium alloys, heat-resisting chromium alloys, or martensitic precipitation hardening alloys. The stainless steel may be subjected to vacuum induction melting (VIM) to provide relatively tight compositional limits and relatively low gas contents for subsequent remelting. The stainless steel may be subjected to vacuum arc remelting (VAR) to produce a relatively high quality ingot with low levels of volatile tramp elements and reduced gas levels. Some preferred stainless steels for use in the inner layer 42 of stainless steel include 316 stainless steel, 316L stainless steel, and 316L VIM/VAR stainless steel.

The outer layer 44 of Tantalum (Ta) can be applied to the inner layer 42 of stainless steel according to known alloying processes such as, for example, by chemical vapor deposition (CVD). Accordingly, the outer layer 44 of Tantalum (Ta) can be conformal with the shape of the inner layer 42 of stainless steel, and provide suitable layer thickness. Thus, the corrosion resistant layered structure 40 can be applied to components having sharp edges such as for example, in one embodiment, an edge formed at an angle of less than about 90° (about 1.57 radians), or in another embodiment, an edge formed at an angle of less than about 45° (about 0.79 radians).

In some embodiments, the outer layer 44 of Tantalum (Ta) can have a thickness 46 that is less than about 100 μm such as, for example, in one embodiment the thickness 46 the outer layer 44 of tantalum can be from about 15 μm to about 75 μm, and in another embodiment the thickness 46 the outer layer 44 of tantalum can be less than about 50 μm. It is noted that the term “layer,” as used herein, means a substantially continuous thickness of material, which may include layer defects, disposed upon another material. Layer defects may include cracks, voids, peeling, inclusions of impurities or excess layer material, pitting, mars nicks, or other manufacturing, surface or material defects. Accordingly, while FIG. 2 depicts idealized layers, any of the layers described herein may include layer defects or any other defect without departing from scope of the present disclosure.

In some embodiments, the outer layer 44 of tantalum can have a low porosity. The porosity of the outer layer 44 of tantalum can be less than about 5% such as for example, in one embodiment less than about 1% or in another embodiment less than about 0.5%. Moreover, it is noted that layer thicknesses and porosity may be determined by analyzing images from a scanning electron microscope (SEM) or any other substantial equivalent technique for measuring layer properties.

The outer layer 44 of Tantalum (Ta) can include various elements in addition to Tantalum (Ta) such as, for example, Bismuth (Bi), Copper (Cu), Hafnium (Hf), Lead (Pb), Niobium (Nb), Platinum (Pt), Tungsten (W), or Zirconium (Zr). Generally, the amount of Tantalum (Ta) in the outer layer 44 of Tantalum (Ta) is at least about 97 wt % such as, for example, in one embodiment at least about 99 wt %, or in another embodiment at least about 99.987 wt %. In one embodiment, the amount of Hafnium (Hf) in the outer layer 44 of Tantalum (Ta) can be greater than 0 wt % and less than about 0.013 wt %. In another embodiment, the amount of Niobium (Nb) in the outer layer 44 of Tantalum (Ta) can be greater than 0 wt % and less than about 0.013 wt %. In yet another embodiment, the amount of Platinum (Pt) in the outer layer 44 of Tantalum (Ta) can be greater than 0 wt % and less than about 0.013 wt %. In a further embodiment, the amount of Tungsten (W) in the outer layer 44 of Tantalum (Ta) can be greater than 0 wt % and less than about 0.013 wt %. It is noted that the wt % of the elements forming the outer layer 44 of Tantalum (Ta) may be determined with laser ablation or any other substantial equivalent technique for measuring layer properties.

Referring collectively to FIGS. 1 and 2, the corrosion resistant layered structure 40 can be applied to various components within the plasma processing chamber 10 to form a corrosion resistant component. Specifically, the corrosion resistant component can be exposed to the plasma processing gas of the plasma processing device 100. In some embodiments, it may be desirable to ensure that each of the corrosion resistant components is not coincident with the plasma region 36 of the plasma processing chamber 10. Accordingly, each of a gas inlet 52, a bellows 54, a conductive strap 56, a conductive gasket 58, or any other component that is exposed to plasma processing gas can comprise the corrosion resistant layered structure 40 to form a corrosion resistant component.

According to the embodiments described herein, a substrate such as, for example, a semiconductor can be processed with plasma and held by the electrostatic chuck 32. The plasma processing chamber 10 can utilize the gas distribution member 20 and electrostatic chuck 32 to form plasma within the plasma region 36. For example, the gas distribution member 20 can include an inner showerhead electrode 22 and an outer electrode 24. The inner shower head electrode 22 and the outer electrode 24 can be electrically grounded by being conductively coupled to an electrical ground 64. The electrostatic chuck 32 can be conductively coupled to an energy source 38, which is capable of transmitting electrical power at one or more frequencies to the electrostatic chuck 32. It is noted that, while a single energy source 38 is depicted in FIG. 1, the electrostatic chuck 32 can be supplied with power from multiple radio frequency power sources that can be independently controlled. Furthermore, it is noted that, while the inner shower head electrode 22 and the outer electrode 24 are depicted in FIG. 1 as being conductively coupled to the electrical ground 64, the inner showerhead electrode 22 and the outer electrode 24 can be supplied with power from one or more radio frequency power sources. Accordingly, the embodiments described herein may make use of any type of capacitively coupled electrode arrangement to generate plasma, i.e., only powered by a showerhead electrode, only powered by a bottom electrode, or powered by a showerhead electrode and a bottom electrode. Additionally, it is noted that the phrase “conductively coupled,” as used herein, means that objects are electrically connected by a conductive material suitable to maintain RF current and/or DC current continuity between the objects.

As depicted in FIG. 1, the inner shower head electrode 22 can be supported by an upper support member 26 and can be in fluidic communication with the gas inlet 52. Accordingly, the inner showerhead electrode 22 can supply plasma processing gas into the plasma region 36. In one embodiment, the gas distribution member 20 can be conductively coupled to the electrical ground 64 via a number of dielectric components and conductive components. As is noted above, each of the conductive components may comprise the corrosion resistant layered structure 40 (FIG. 2).

Specifically, the gas distribution member 20 can be in contact with and conductively coupled to a containment shroud 50. The containment shroud 50 is configured to enclose the plasma region 36 and substantially confine any plasma within the plasma region 36. The containment shroud 50 can be formed from a dielectric material. In one embodiment, the containment shroud 50 can be suspended from the upper support member 26 and conductively coupled to a lower shroud member 51. The conductive gasket 58 can be located between the containment shroud 50 and the lower shroud member 51 to form a seal to contain plasma processing gas. Accordingly, the conductive gasket 58 can be conductively coupled to both the gas containment shroud 50 and the lower shroud member 51. It is noted that, while the containment shroud 50 is depicted as an integral component, the containment shroud may include any number of components that are conductively coupled with one another. Moreover, the embodiments described herein can comprise one or more gaskets, each of which can comprise the corrosion resistant layered structure 40.

In some embodiments, the gas distribution member 20 and the containment shroud 50 can move relative to the substrate support member 30. For example, the upper support member 26 can be configured to move vertically (substantially along the Y-axis) during and/or after plasma processing. In one embodiment, the upper support member 26 can be coupled to a gap adjustment actuator 60 that is operable to raise and/or lower the upper support member 26. As used herein the term actuator means a device capable of transforming an input signal into motion such as, for example, linear device, a rotary device, a pneumatic device, an electrical device, a hydraulic device, and the like. A portion of the gap adjustment actuator 60 can be located within plasma processing chamber 10 outside of the plasma region 36. Accordingly, the gap adjustment actuator 60 can be protected from plasma processing gas by the bellows 54, which can comprise the corrosion resistant layered structure 40 (FIG. 2). The bellows 54 is a hollow member that that may substantially seal the gap adjustment actuator 60 and substantially prevent plasma processing gas from interacting with the gap adjustment actuator 60. The bellows 54 can be formed with furrows and ridges to allow the gap adjustment actuator 60 to move, extend, and/or retract (e.g., during processing, loading or unloading substrates, etc.).

Referring still to FIG. 1, the containment shroud 50 can be coupled to the upper support member 26. Thus, the gap adjustment actuator 60 can cause relative motion between the containment shroud 50 and the substrate support member 30. To accommodate relative motion between the containment shroud 50 and the substrate support member 30, the containment shroud 50 and the outer alignment member 34 of the substrate support member 30 can be separated by a gap 70. In some embodiments, a conductive strap 56 can be physically coupled to the lower shroud member 51 and the outer alignment member 34 to prevent arcing over the gap 70. The conductive strap 56 is flexible and can comprise the corrosion resistant layered structure 40 (FIG. 2). The conductive strap 56 is configured to conductively couple the outer alignment member 34 and the lower shroud member 51 and to allow relative motion between the outer alignment member 34 and the lower shroud member 51 without losing the conductive coupling. Accordingly, the gas distribution member 20, the containment shroud 50, the lower shroud member 51, the outer alignment member 34, the conductive strap 56 and the conductive gasket 58 can be conductively coupled with each other and maintained at a substantially uniform DC voltage.

The gas inlet 52 can be in fluid communication with the upper support member, which can be in fluid communication with gas passages of the gas distribution member 20. Accordingly, plasma processing gas can be supplied to the plasma region 36 of the plasma processing chamber 10 via the gas inlet 52 and the gas distribution member 20. Because the gas inlet 52 is exposed to plasma processing gas outside of the plasma region 36, it may be desirable for the gas inlet 52 to comprise the corrosion resistant layered structure 40 (FIG. 2). For the purpose defining and describing the present disclosure, it is noted that the phrase “fluid communication,” as used herein, means the exchange of fluid from one object to another object, which may include, for example, the flow of compressible and incompressible fluids.

Plasma can be generated within the plasma region 36 of the plasma processing chamber 10 by igniting plasma processing gas with RF energy supplied by the energy source 38. Plasma can be ignited using a conductively coupled arrangement, as described herein above. Accordingly, a substrate can be processed with plasma formed by igniting plasma process gas. After the substrate has been processed (e.g., a semiconductor substrate has been plasma etched), the RF power and thus the plasma can be shut down. The processed substrate can then be removed from the substrate support member 30.

In one embodiment, the substrate support member 30 can be operatively coupled with a lift pin actuator 62 that is configured to physically separate the substrate from the electrostatic chuck 32. The lift pin actuator 62 can be located within the plasma processing chamber 10 and outside of the plasma region 36. Thus, the lift pin actuator 62 can be protected from plasma processing gas by the bellows 54, which can comprise the corrosion resistant layered structure 40 (FIG. 2). The bellows 54 can be exposed to the plasma processing gas and substantially prevent plasma processing gas from interacting with the lift pin actuator 62.

It should now be understood that each of the gas inlet 52 (or any other portion of a gas line), the bellows 54, the conductive strap 56, and the conductive gasket 58 can be formed into a corrosion resistant component, when each of their respective outer most layers are formed from the corrosion resistant layered structure 40. Accordingly, with reference to FIG. 2, the outer layer 44 of Tantalum (Ta) of the corrosion resistant layered structure 40 can be exposed to plasma processing gas outside of the plasma region 36. In some embodiments, it may be desirable to utilize the corrosion resistant layered structure 40 on components that are exposed to plasma processing gas comprising caustic gases such as, for example, BCl₃, HBr, HCl, Cl₂, or a combination thereof. In further embodiments, it may be desirable to utilize the corrosion resistant layered structure 40 on components that are exposed to plasma processing gas comprising CO.

For the purposes of describing and defining the present disclosure it is noted that the terms “substantially” and “about” are utilized herein to represent the inherent degree of uncertainty that may be attributed to any quantitative comparison, value, measurement, or other representation. The terms “substantially” and “about” are also utilized herein to represent the degree by which a quantitative representation may vary from a stated reference without resulting in a change in the basic function of the subject matter at issue.

It is noted that the term “commonly,” when utilized herein, is not utilized to limit the scope of the claims or to imply that certain features are critical, essential, or even important to the structure or function of the claims. Rather, these terms are merely intended to identify particular aspects of an embodiment of the present disclosure or to emphasize alternative or additional features that may or may not be utilized in a particular embodiment of the present disclosure. Similarly, although some aspects of the present disclosure are identified herein as preferred or particularly advantageous, it is contemplated that the present disclosure is not necessarily limited to these preferred aspects of the disclosure.

Having described the invention in detail and by reference to specific embodiments thereof, it will be apparent that modifications and variations are possible without departing from the scope of the invention defined in the appended claims.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

What is claimed is:

1. A plasma processing device comprising a plasma processing chamber, a gas distribution member, a substrate support member, a plasma region, an energy source, and a corrosion resistant component, wherein:
the plasma processing chamber is maintained at a vacuum pressure and confines a plasma processing gas;
the gas distribution member and the substrate support member are disposed within the plasma processing chamber;
the gas distribution member emits the plasma processing gas within the plasma processing chamber;
the gas distribution member and the substrate support member are separated from one another by the plasma region;
the energy source is in electrical communication with the gas distribution member, the substrate support member, or both;
the energy source transmits energy into the plasma processing chamber and transforms at least a portion of the plasma processing gas into plasma within the plasma region;
the corrosion resistant component is located within the plasma processing chamber;
the corrosion resistant component is exposed to the plasma processing gas and is not coincident with the plasma region; and
the corrosion resistant component comprises an inner layer of stainless steel that is coated with an outer layer of Tantalum (Ta).

2. The plasma processing device of claim 1, wherein the outer layer of Tantalum (Ta) is chemical vapor deposition layer.

3. The plasma processing device of claim 1, wherein the outer layer of Tantalum (Ta) has a thickness of less than about 100 μm.

4. The plasma processing device of claim 1, wherein the outer layer of Tantalum (Ta) has a porosity of less than about 5%.

5. The plasma processing device of claim 1, wherein the outer layer of Tantalum (Ta) comprises at least about 97 wt % of Tantalum (Ta).

6. The plasma processing device of claim 1, wherein the outer layer of Tantalum (Ta) comprises greater than 0 wt % and less than about 0.013 wt % of Hafnium (Hf).

7. The plasma processing device of claim 1, wherein the outer layer of Tantalum (Ta) comprises greater than 0 wt % and less than about 0.013 wt % of Niobium (Nb).

8. The plasma processing device of claim 1, wherein the outer layer of Tantalum (Ta) comprises greater than 0 wt % and less than about 0.013 wt % of Platinum (Pt).

9. The plasma processing device of claim 1, wherein the outer layer of Tantalum (Ta) comprises greater than 0 wt % and less than about 0.013 wt % of Tungsten (W).

10. The plasma processing device of claim 1, wherein the corrosion resistant component is a gasket.

11. The plasma processing device of claim 1, wherein the corrosion resistant component is a bellows.

12. The plasma processing device of claim 1, wherein the corrosion resistant component is a conductive strap.

13. The plasma processing device of claim 1, wherein the corrosion resistant component is a gas line.

14. The plasma processing device of claim 1, wherein the corrosion resistant component comprises an edge formed at an angle of less than about 90° (about 1.57 radians).

15. The plasma processing device of claim 1, wherein the plasma processing gas comprises BCl₃, HBr, HCl, Cl₂, or a combination, and the outer layer of Tantalum (Ta) of the corrosion resistant component is exposed to the plasma processing gas.

16. The plasma processing device of claim 1, wherein the plasma processing gas comprises CO, and the outer layer of Tantalum (Ta) of the corrosion resistant component is exposed to the plasma processing gas.

17. A plasma processing device comprising a plasma processing chamber, a gas distribution member, a substrate support member, a plasma region, an energy source, and a corrosion resistant component, wherein:
the plasma processing chamber is maintained at a vacuum pressure and confines a plasma processing gas;
the gas distribution member and the substrate support member are disposed within the plasma processing chamber;
the gas distribution member emits the plasma processing gas within the plasma processing chamber;
the gas distribution member and the substrate support member are separated from one another by the plasma region;
the energy source is in electrical communication with the gas distribution member, the substrate support member, or both;
the energy source transmits energy into the plasma processing chamber and transforms at least a portion of the plasma processing gas into plasma within the plasma region;
the corrosion resistant component is located within the plasma processing chamber;
the corrosion resistant component is exposed to the plasma processing gas and is not coincident with the plasma region;
the corrosion resistant component comprises an inner layer of stainless steel that is coated with an outer layer of Tantalum (Ta);
the outer layer of Tantalum (Ta) has a thickness of less than about 100 μm;
the outer layer of Tantalum (Ta) has a porosity of less than about 5%; and
the outer layer of Tantalum (Ta) comprises at least about 97 wt % of Tantalum (Ta).
